(19) United States
(12) Patent Application Publication
(10) Pub. No.: US 2012/0236660 A1
(43) Pub. Date: Sep. 20, 2012

(54) TEST SYSTEM AND TEST METHOD FOR MEMORY

(75) Inventor: Yung Ching YANG, Luzhu Township (TW)

(73) Assignee: NANYA TECHNOLOGY CORP., Kueishan (TW)

(21) Appl. No.: 13/049,036

(22) Filed: Mar. 16, 2011

(51) Int. Cl. G11C 7/00

(52) U.S. Cl. 365/189.07

(57) ABSTRACT

The test system for memory includes a controlling device, an address generating device, a data disturbing device and a comparing device. The controlling device is used for writing a first data into a memory. The address generating device is used for generating a plurality of first addresses and a plurality of second addresses corresponding to the memory. The data disturbing device is used for disturbing the first data using the first addresses to obtain a second data, and disturbing the second data using the second addresses to obtain a third data. The comparing device is used to for comparing the third data and the first data.

### 1. TECHNICAL FIELD

The present invention relates to a test system and a test method, and more particularly, relates to a test system and a test method for memory.

### 2. BACKGROUND

The conventional test system for memory must generate one or more precisive address of the memory, then the data in the address are tested. Usually, the conventional test system for memory includes a test machine and a system platform. The test machine receives the addresses from the system platform, and fetches the data according to the addresses to perform the test. However, user can not understand the operation in the test system, and cannot detect the error in the test system.

Additionally, owing to different system platform, the methods for generating the addresses are different so that the methods cannot be applied to various system platforms or the test machines. Besides, the conventional method for generating the addresses is complex. Furthermore, it takes times for the test in the system platform.

### SUMMARY

In view of the above problems, the present invention provides an embodied test system for memory comprising a controlling device, an address generating device, a data disturbing device and a comparing device. The controlling device is used for writing a first data into a memory. The address generating device is used for generating a plurality of first addresses and a plurality of second addresses corresponding to the memory. The data disturbing device is used for disturbing the first data using the first addresses to obtain a second data, and disturbing the second data using the second addresses to obtain a third data. The comparing device is used for comparing the third data and the first data.

The present invention further provides a test method for memory, comprising the steps of: writing a first data into a memory; generating a plurality of first addresses corresponding to the memory; disturbing the first data using the first addresses to obtain a second data; generating a plurality of second addresses corresponding to the memory; disturbing the second data using the second addresses to obtain a third data; comparing the third data and the first data.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 is a flow chart of a test method according to one embodiment of the present invention; and

FIG. 2 is a block diagram of a test system according to one embodiment of the present invention.

### DETAILED DESCRIPTION

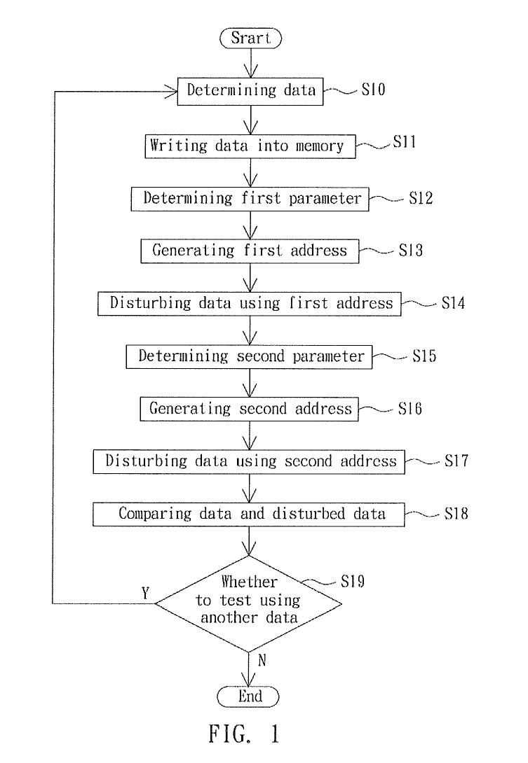

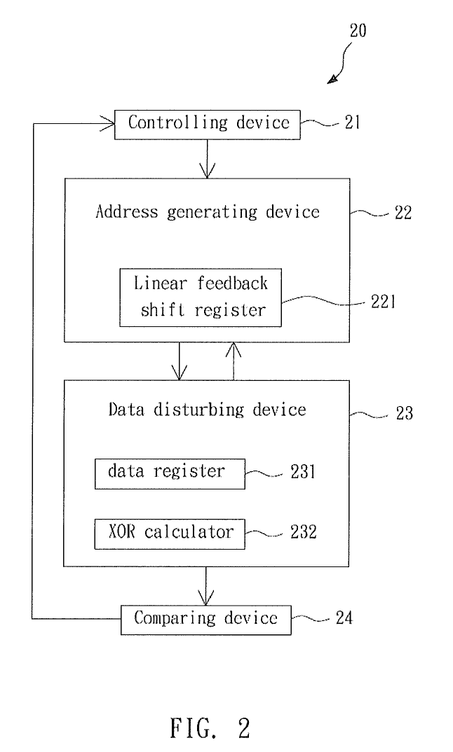

FIG. 1 is a flow chart of a test method according to one embodiment of the present invention, and FIG. 2 is a block diagram of a test system according to one embodiment of the present invention. The test system and the test method of the invention can be use for testing a memory, for example, DRAM. Referring to FIGS. 1 and 2, the test system 20 for memory comprises a controlling device 21, an address generating device 22, a data disturbing device 23 and a comparing device 24. The controlling device 21 is used for writing a first data into a memory as shown in step S11. In one embodiment, the controlling device 21 can be used for determining the first data before writing the first data into the memory as shown in step S10. For example, the first data may be #00 (Hex.) or #FF (Hex.).

The address generating device 22 is used for generating a plurality of first addresses corresponding to the memory as shown in step S13. The address generating device 22 includes a linear feedback shift register 221 for generating the first addresses. The linear feedback shift register 221 includes a plurality of first parameters used for generating the first addresses as shown in step S12 before step S13. The address generating device 22 includes a plurality of range parameters according to the memory, a type of the linear feedback shift register, a total bit number of the linear feedback shift register, a first corresponding position of EXOR Gate of the linear feedback shift register, a first relation between the range parameters and the corresponding bit in the linear feedback shift register, a first operation equation of the linear feedback shift register, a first initial value and an overall loop number to generate the first addresses.

In one embodiment, the range parameters are determining according to the memory, for example, 2 GB Module is taken as an embodiment of the invention, the range parameters are as follows. According to different testing module, the range parameters are different.

| Target Type | Configuration | Rank | Bank | Row | Col |
|---|---|---|---|---|---|
| 1 GB | Minga/128 × 8 16 devices | (N/A) | 8 | 2¹⁴ | 2¹⁰ |
| Component | | | | | |
| 2 GB Module | Minga/128 × 8 16 devices | 1 | 8 | 2¹⁴ | 2¹⁰ |
| 2 GB Module | Minga/128 × 8 16 devices | 2 | 8 | 2¹⁴ | 2¹⁰ |

Then, the type of the linear feedback shift register (LSFR) is determined. Usually, there are two types of the linear feedback shift register: Fibonacci type LFSR (out-of-line type LSFR) and Galois type LFSR (in-line type LSFR). In this embodiment, the in-line type LSFR is used to generate random value.

Next, the total bit number of the linear feedback shift register 221 is determined. As stated in the above, the range parameters are determined for 2 GB Module DRAM, the range and the necessary bit number for the range parameters are as follows. For the 2 GB Minga DIMM Module, its BL is 8, therefore, the total bit number is 25 bits (1+3+14+7).

| Item | Range | Bit number |
|---|---|---|
| Rank | 0, 1 | 1 |
| Bank | 0~7 | 3 |
| Row | 0~16383 | 14 |
| Col | 0~1023 | 10 − log2BL = 7 |

Thereafter, the first corresponding position of EXOR Gate of the linear feedback shift register 221 is determined. Using the step, the bits of the range parameters, such as Rank, Bank, Row and Col, can be simulated as linear addresses in one dimension.

Then, the first relation between the range parameters and the corresponding bit in the linear feedback shift register 221, and the first operation equation of the linear feedback shift register 221 are determined as follows.

| | 13 | 12 | 11 | 10 | 9 | 8 | 7 | 6 | 5 | 4 | 3 | 2 | 1 | 0 |
|---|---|---|---|---|---|---|---|---|---|---|---|---|---|---|
| Rank | | | | | | | | | | | | | | 24 |
| Bank | | | | | | | | | | | | 23 ⊕ 10 | 22 ⊕ 11 | 21 ⊕ 12 |
| Row | 18 | 19 | 20 | 17 | 16 | 15 | 14 | 13 | 12 | 11 | 10 | 9 | 8 | 7 |
| Col | | | | | 6 | 5 | 4 | 3 | 2 | 1 | 0 | Value | Value | Value |
| | | | | | | | | | | | | Fix to 0 | Fix to 0 | Fix to 0 |

In this embodiment, the Bank bits are the XOR result of 23th bit and 10th bit, 22th bit and 11th bit, 21th bit and 12th bit so that the addresses generated by the linear feedback shift register 221 are similar to those by PC (Personal Computer). The first relation and the first operation equation are programmable.

Next, the first initial value and the overall loop number are determined to generate the first addresses. In the in-line type LSFR, the first initial value cannot be zero. The range of the first initial value is 1 to (2²⁵−1). The overall loop number is 2²⁵−1. Therefore, the address generating device 22 can generate the random first addresses in first sequences.

The data disturbing device 23 is used for disturbing the first data using the first addresses to obtain a second data as shown in step S14. In one embodiment, the data disturbing device 23 is used for reading the first data of the memory according to the first addresses. For example, the first address generated from the address generating device 22 is as follows.

| | |
|---|---|
| Rank | 0x01 |
| Bank | 0x03 |
| Row | 0x0050 |
| Col | 0x0100h |

Next, the first data is stored into a data register 231. For example, the eight first data are read and stored into the data register 231 according to above first address.

Tmp_Data_0 (8 bits)
Tmp_Data_1 (8 bits)
Tmp_Data_2 (8 bits)
Tmp_Data_3 (8 bits)
Tmp_Data_4 (8 bits)
Tmp_Data_5 (8 bits)
Tmp_Data_6 (8 bits)
Tmp_Data_7 (8 bits)

Then, the data disturbing device 23 is used for calculating the second data according to the first data and the corresponding first addresses. In this embodiment, the data disturbing device 23 comprises an XOR calculator 232 for performing XOR operation in the first data and the corresponding first addresses to obtain the second data. The operation equations are as follows.

New_Tmp_Data_{—}0=Tmp_Data_{—}0⊕(!((Row⊕(Col+0))&0xff)

New_Tmp_Data_{—}1=Tmp_Data_{—}1⊕(!((Row⊕(Col+1))&0xff)

New_Tmp_Data_{—}2=Tmp_Data_{—}2⊕(!((Row⊕(Col+2))&0xff)

New_Tmp_Data_{—}3=Tmp_Data_{—}3⊕(!((Row⊕(Col+3))&0xff)

New_Tmp_Data_{—}4=Tmp_Data_{—}4⊕(!((Row⊕(Col+4))&0xff)

New_Tmp_Data_{—}5=Tmp_Data_{—}5⊕(!((Row⊕(Col+5))&0xff)

New_Tmp_Data_{—}6=Tmp_Data_{—}6⊕(!((Row⊕(Col+6))&0xff)

New_Tmp_Data_{—}7=Tmp_Data_{—}7⊕(!((Row⊕(Col+7))&0xff)

Thereafter, the calculated second data is stored into the data register 231 and the memory according to the corresponding first addresses, that is, the calculated second data is stored into the original first addresses of the memory.

Then, the address generating device 22 is used for generating a plurality of second addresses corresponding to the memory as shown in step S16. The linear feedback shift register 221 includes a plurality of second parameters used for generating the second addresses as shown in step S15 before step S16. The address generating device 22 further comprises a second corresponding position of EXOR Gate of the linear feedback shift register; a second relation between the range parameters and the corresponding bit in the linear feedback shift register, a second operation equation of the linear feedback shift register; and a second initial value to generate the second addresses.

In this embodiment, the range parameters, the type of the linear feedback shift register (LSFR) and the total bit number of the linear feedback shift register are the same as those in generating the first addresses.

However, the second corresponding position of EXOR Gate of the linear feedback shift register should be determined so that the second corresponding position of EXOR Gate is different from the first corresponding position of EXOR Gate. Furthermore, the second relation between the range parameters and the corresponding bit in the linear feedback shift register, and the second operation equation of the linear feedback shift register also should be determined to be different from the first relation between the range parameters and the corresponding bit in the linear feedback shift register and the first operation equation.

Next, the second initial value is determined to generate the second addresses. Also, the second initial value cannot be zero. Therefore, the address generating device 22 can generate the random second addresses in second sequences being different from the random first addresses in first sequences.

Then, the data disturbing device 23 is used for disturbing the second data using the second addresses to obtain a third data as shown in step S17. In one embodiment, the data disturbing device 23 is used for reading the second data of the memory according to the second addresses. Next, the second data is stored into the data register 231. Then, the data disturbing device 23 is used for calculating the third data according to the second data and the corresponding second addresses. In this embodiment, the XOR calculator 232 is used for performing XOR operation in the second data and the corresponding second addresses to obtain the third data.

As stated in the above, the first data and the first addresses are calculated using XOR operation to obtain the second data. Now, the second data and the second addresses are calculated using XOR operation to obtain the third data. According to the basic XOR operation principle, a first variable Y and a second variable M are calculated using XOR operation to obtain a third variable Z, and the result of XOR operation in the third variable Z and the second variable M is equal to the original first variable Y. The operation equations are as follows.

(Y XOR M)=Z

(Z XOR M)=Y

Therefore, after performing XOR operation twice using the same variable M, the original variable Y can maintain and does not change. In this embodiment, the first addresses in the first sequences are different from the second addresses in the second sequences, and the meaning is that the calculating sequences are different. However, the data are stored in the same addresses. That is, the first data and their addresses are calculated using XOR operation. Therefore, after performing XOR operation twice using the same addresses, the third data should be equal to the first data, if the memory is good.

The comparing device 24 is used for comparing the third data and the first data as shown in step S18. If the third data is equal to the first data, the memory can be tested to be good using the test method and the test system 20 of the invention.

Furthermore, the controlling device 21 is used for determining whether to test the memory using another data as shown in step S19. For example, another data #AA (Hex.) can be used to be the first data to test the memory again.

Using the test method and the test system 20 of the invention, the addresses can be generated simply and randomly in one dimension to simulate the test environment, and the parameters (e.g. Rank, Bank, Row, Col) related to the addresses can be programmable to apply to different type of the memory so as to extend the coverage for the testing memory. The test method and the test system 20 of the invention are compatible for various test machines. Furthermore, the defect in the memory can be found early and be amended to reduce the number of the bad die during the testing stage.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A test system for memory, comprising:
a controlling device, for writing a first data into a memory;
an address generating device, for generating a plurality of first addresses and a plurality of second addresses corresponding to the memory;
a data disturbing device, for disturbing the first data using the first addresses to obtain a second data, and disturbing the second data using the second addresses to obtain a third data; and
a comparing device, for comparing the third data and the first data.

2. The test system of claim 1, wherein the controlling device is used for determining the first data.

3. The test system of claim 1, wherein the address generating device comprises a linear feedback shift register for generating the first addresses and the second addresses.

4. The test system of claim 3, wherein the linear feedback shift register comprises a plurality of first parameters and a plurality of second parameters respectively used for the first addresses and the second addresses.

5. The test system of claim 4, wherein the address generating device comprises a plurality of range parameters according to the memory, a type of the linear feedback shift register, a total bit number of the linear feedback shift register; a first corresponding position of EXOR Gate of the linear feedback shift register; a first relation between the range parameters and the corresponding bit in the linear feedback shift register, a first operation equation of the linear feedback shift register, a first initial value and an overall loop number to generate the first addresses.

6. The test system of claim 1, wherein the data disturbing device is used for reading the first data of the memory according to the first addresses; storing the first data into a data register; calculating the second data according to the first data and the corresponding first addresses; and storing the second data into the memory according to the corresponding first addresses.

7. The test system of claim 6, wherein the data disturbing device comprises an XOR calculator for performing XOR operation in the first data and the corresponding first addresses to obtain the second data.

8. The test system of claim 5, wherein the address generating device further comprises a second corresponding position of EXOR Gate of the linear feedback shift register, a second relation between the range parameters and the corresponding bit in the linear feedback shift register, a second operation equation of the linear feedback shift register, and a second initial value to generate the second addresses.

9. The test system of claim 7, wherein the data disturbing device is used for reading the second data of the memory according to the second addresses; storing the second data into the data register; calculating the third data according to the second data and the corresponding second addresses; and storing the third data into the memory according to the corresponding second addresses.

10. The test system of claim 9, wherein the XOR calculator is used for performing XOR operation in the second data and the corresponding second addresses to obtain the third data.

11. The test system of claim 1, wherein the controlling device is used for determining whether to test the memory using another data.

12. A test method for memory, comprising the steps of:
writing a first data into a memory;
generating a plurality of first addresses corresponding to the memory;
disturbing the first data using the first addresses to obtain a second data;
generating a plurality of second addresses corresponding to the memory;
disturbing the second data using the second addresses to obtain a third data; and
comparing the third data and the first data.

13. The test method of claim 12, wherein the step of writing the first data into the memory further comprises a step of determining the first data.

14. The test method of claim 12, wherein a linear feedback shift register is used to generate the first addresses and the second addresses.

15. The test method of claim 14, wherein the steps of generating the first addresses and the second addresses further comprise a step of determining a plurality of first parameters and a plurality of second parameters of the linear feedback shift register respectively used for the first addresses and the second addresses.

16. The test method of claim 15, wherein the step of generating the first addresses further comprise the steps of:
determining a plurality of range parameters according to the memory;
determining a type of the linear feedback shift register;
determining a total bit number of the linear feedback shift register;
determining a first corresponding position of EXOR Gate of the linear feedback shift register;
determining a first relation between the range parameters and the corresponding bit in the linear feedback shift register, and the first operation equation of the linear feedback shift register; and
determining a first initial value and an overall loop number.

17. The test method of claim 12, wherein the step of disturbing the first data using the first addresses to obtain the second data comprises the steps of:
reading the first data of the memory according to the first addresses;
storing the first data into a data register;
calculating the second data according to the first data and the corresponding first addresses; and
storing the second data into the memory according to the corresponding first addresses.

18. The test method of claim 17, wherein an XOR operation is performed to calculate the first data and the corresponding first addresses to obtain the second data.

19. The test method of claim 16, wherein the step of generating the second addresses further comprise the steps of:
determining a second corresponding position of EXOR Gate of the linear feedback shift register;
determining a second relation between the range parameters and the corresponding bit in the linear feedback shift register, and the second operation equation of the linear feedback shift register; and
determining a second initial value.

20. The test method of claim 12, wherein the step of disturbing the second data using the second addresses to obtain the third data comprises the steps of:
reading the second data of the memory according to the second addresses;
storing the second data into a data register;
calculating the third data according to the second data and the corresponding second addresses; and
storing the third data into the memory according to the corresponding second addresses.

21. The test method of claim 20, wherein an XOR operation is performed to calculate the second data and the corresponding second addresses to obtain the third data.

22. The test method of claim 12, further comprising a step of determining whether to test the memory using another data after the step of comparing the third data and the first data.
